(19) United States
(12) Patent Application Publication
(10) Pub. No.: US 2024/0079307 A1
(43) Pub. Date: Mar. 7, 2024

(54) PACKAGE COMPRISING A SUBSTRATE WITH POST INTERCONNECTS HAVING A PROFILE CROSS SECTION OF A TRAPEZOID SHAPE

(71) Applicant: QUALCOMM Incorporated, San Diego, CA (US)

(72) Inventors: Wei WANG, San Diego, CA (US); Kuiwon KANG, San Diego, CA (US); Michelle Yejin KIM, Carlsbad, CA (US); Ahmer SYED, San Diego, CA (US)

(21) Appl. No.: 17/939,769

(22) Filed: Sep. 7, 2022

(51) Int. Cl. H01L 23/498; H01L 21/48; H01L 23/00

(52) U.S. Cl. CPC H01L 23/49838; H01L 21/4857; H01L 21/486; H01L 23/49816; H01L 23/49822; H01L 24/16; H01L 2224/16227; H01L 2224/16238; H01L 2924/35121

(57) ABSTRACT

A package comprising an integrated device and a substrate coupled to the integrated device. The substrate comprises at least one dielectric layer and a plurality of interconnects. The plurality of interconnects include a plurality of post interconnects. The plurality of post interconnects include a post interconnect comprising a profile cross section that includes a trapezoid shape.

### FIELD

Various features relate to packages with a substrate and integrated device.

### BACKGROUND

A package may include a substrate and integrated devices. These components are coupled together to provide a package that may perform various functions. The performance of a package and its components may depend on the quality of the joints between various components of the package. There is an ongoing need to provide packages that include robust and reliable joints between components.

### SUMMARY

Various features relate to packages with a substrate and integrated device.

One example provides a package comprising an integrated device and a substrate coupled to the integrated device. The substrate comprises at least one dielectric layer and a plurality of interconnects. The plurality of interconnects include a plurality of post interconnects. The plurality of post interconnects include a post interconnect comprising a profile cross section that includes a trapezoid shape.

Another example provides a device that includes a package. The package comprises an integrated device and a substrate coupled to the integrated device. The substrate comprises at least one dielectric layer and a plurality of interconnects. The plurality of interconnects include a plurality of post interconnects. The plurality of post interconnects include a post interconnect comprising a profile cross section that includes a trapezoid shape.

Another example provides a method for fabricating a package. The method provides a substrate comprising at least one dielectric layer and a plurality of interconnects. The plurality of interconnects include a plurality of post interconnects. The plurality of post interconnects include a post interconnect comprising a profile cross section that includes a trapezoid shape. The method couples an integrated device to the substrate through the plurality of post interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile cross sectional view of an exemplary integrated device.

FIG. 2 illustrates a profile cross sectional view of an integrated device coupled to a substrate comprising post interconnects with a trapezoid profile shape.

FIG. 3 illustrates a profile cross sectional view of an integrated device coupled to a substrate comprising post interconnects with a trapezoid profile shape.

FIG. 4 illustrates a profile cross sectional view of a package comprising an integrated device coupled to a substrate comprising post interconnects with a trapezoid profile shape.

FIG. 5 illustrates a profile cross sectional view of a package comprising an integrated device coupled to a substrate comprising post interconnects with a trapezoid profile shape.

FIG. 6 illustrates a profile cross sectional view of a package comprising an integrated device coupled to a substrate comprising post interconnects with a trapezoid profile shape.

FIGS. 7A-7D illustrate an exemplary sequence for fabricating a substrate with post interconnects with a trapezoid profile shape.

FIGS. 8A-8D illustrate an exemplary sequence for fabricating a substrate with post interconnects with a trapezoid profile shape.

FIGS. 9A-9B illustrate an exemplary sequence for fabricating a substrate with post interconnects with a trapezoid profile shape.

FIGS. 10A-10C illustrate an exemplary sequence for fabricating a substrate with post interconnects with a trapezoid profile shape.

device that includes pillar interconnects.

FIG. 11 illustrates an exemplary sequence for fabricating a package comprising a substrate with post interconnects with a trapezoid profile shape.

FIG. 12 illustrates an exemplary flow diagram of a method for fabricating a package comprising a substrate with post interconnects with a trapezoid profile shape.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device and a substrate coupled to the integrated device. The substrate comprises at least one dielectric layer and a plurality of interconnects. The plurality of interconnects include a plurality of post interconnects. The plurality of post interconnects include a post interconnect comprising a profile cross section that includes a trapezoid shape. The integrated device may be coupled to the substrate through the plurality of post interconnects and a plurality of solder interconnects. The plurality of solder interconnects may be located between the integrated device and the plurality of post interconnects. The use of varying widths of the post interconnects helps reduce stress on the dielectric layers of the integrated device, which helps reduce the likelihood of delamination of the dielectric layers of the integrated device. Moreover, the more robust and reliable joint helps provide a more reliable electrical path for currents and/or signals traveling between the integrated device and the substrate, which can lead to improved performances for the integrated device and the package.

### Exemplary Package Comprising an Integrated Device and a Substrate Comprising a Post Interconnect

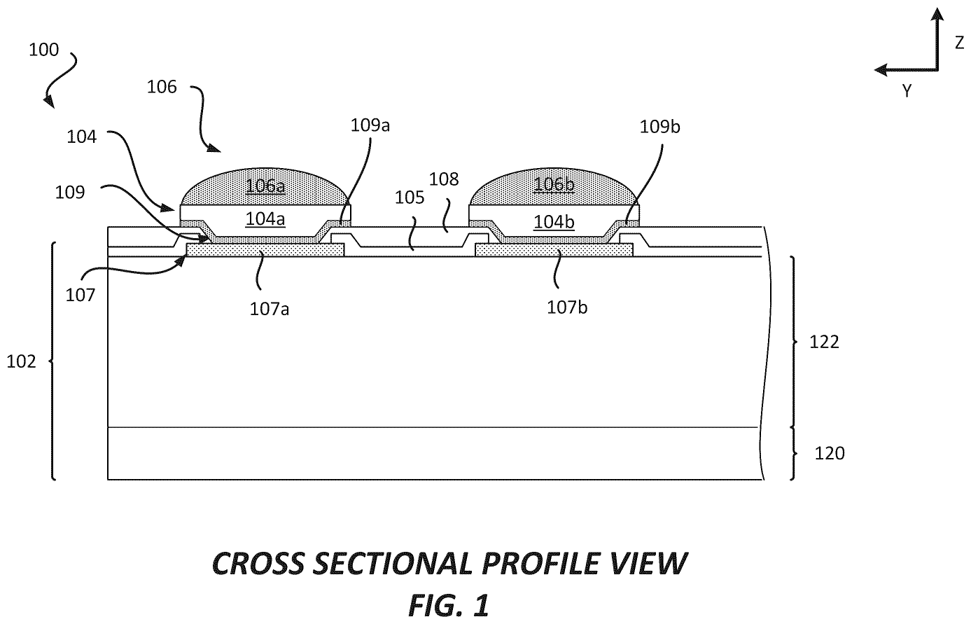

FIG. 1 illustrates a profile cross sectional view of an integrated device 100. As will be further described below, the integrated device 100 may be coupled to a substrate through a plurality of post interconnects of the substrate. The integrated device 100 includes a die portion 102, a plurality of pillar interconnects 104 and a plurality of solder interconnects 106. The plurality of pillar interconnects 104 are coupled to the die portion 102. The plurality of solder interconnects 106 are coupled to the plurality of pillar interconnects 104. The integrated device 100 may include a flip chip.

The die portion 102 includes a die substrate 120, an interconnect portion 122, a passivation layer 105, a plurality of pads 107, a passivation layer 108 and a plurality of under bump metallization interconnects 109. The die substrate 120 may include silicon (Si). A plurality of cells (e.g., logic cells) and/or a plurality of transistors (not shown) may be formed in and/or over the die substrate 120. Different implementations may use different types of transistors, such as a field effect transistor (FET), planar FET, finFET, and a gate all around FET. In some implementations, a front end of line (FEOL) process may be used to fabricate the plurality of cells (e.g., logic cells) and/or transistors in and/or over the die substrate 120. The interconnect portion 122 is located over and coupled to the die substrate 120. The interconnect portion 122 may be coupled to the plurality of cells and/or transistors located in and/or over the die substrate 120. The interconnect portion 122 (e.g., die interconnect portion) may include a plurality of die interconnects (not shown) that are coupled to the plurality of cells and/or transistors. In some implementations, a back end of line (BEOL) process may be used to fabricate the interconnect portion 122.

The passivation layer 105 is located over and coupled to the interconnect portion 122. The passivation layer 105 may be a hard passivation layer. The passivation layer 108 is located over the passivation layer 105. The passivation layer 108 may include a polymer passivation layer. The plurality of pads 107 are located over the interconnect portion 122. The plurality of pads 107 may be coupled to die interconnects of the interconnect portion 122. In some implementations, the passivation layer 105, the passivation layer 108 and/or the plurality of pads 107 may be considered part of the interconnect portion 122. In some implementations, a back end of line (BEOL) process may be used to fabricate the passivation layer 105, the passivation layer 108 and the plurality of pads 107. The plurality of under bump metallization interconnects 109 are coupled to the plurality of pads 107. The plurality of under bump metallization interconnects 109 may be located over the plurality of pads 107. In some implementations, there may be additional interconnects between the plurality of pads 107 and the plurality of under bump metallization interconnects 109. For example, there may be metallization interconnects between the plurality of pads 107 and the plurality of under bump metallization interconnects 109. Examples of metallization interconnects include redistribution interconnects. In some implementations, the plurality of under bump metallization interconnects 109 may be coupled to the plurality of pads 107 through metallization interconnects (e.g., redistribution interconnects).

The plurality of pillar interconnects 104 may be coupled to the die portion 102. The plurality of pillar interconnects 104 may be coupled to the plurality of under bump metallization interconnects 109. The plurality of pillar interconnects 104 may be coupled to the die portion 102 through the plurality of under bump metallization interconnects 109. The plurality of pillar interconnects 104 may be a means for pillar interconnection. The plurality of under bump metallization interconnects 109 may be a means for under bump metallization interconnection.

The plurality of pads 107 include a first pad 107a and a second pad 107b. The plurality of under bump metallization interconnects 109 include a first under bump metallization interconnect 109a and a second under bump metallization interconnect 109b. The plurality of pillar interconnects 104 include a first pillar interconnect 104a and a second pillar interconnect 104b. The plurality of solder interconnect 106 include a first solder interconnect 106a and a second solder interconnect 106b.

The first under bump metallization interconnect 109a is coupled to the first pad 107a. The first pillar interconnect 104a is coupled to the first under bump metallization interconnect 109a. The first solder interconnect 106a is coupled to the first pillar interconnect 104a. It is noted that in some implementations, the first pillar interconnect 104a is coupled to the first under bump metallization interconnect 109a through at least one metallization interconnect. That is, at least one metallization interconnect (e.g., redistribution interconnect) may be located between the first pillar interconnect 104a and the first under bump metallization interconnect 109a.

The second under bump metallization interconnect 109b is coupled to the second pad 107b. The second pillar interconnect 104b is coupled to the second under bump metallization interconnect 109b. The second solder interconnect 106b is coupled to the second pillar interconnect 104b. It is noted that in some implementations, the second pillar interconnect 104b is coupled to the second under bump metallization interconnect 109b through at least one metallization interconnect. That is, at least one metallization interconnect (e.g., redistribution interconnect) may be located between the second pillar interconnect 104b and the second under bump metallization interconnect 109b.

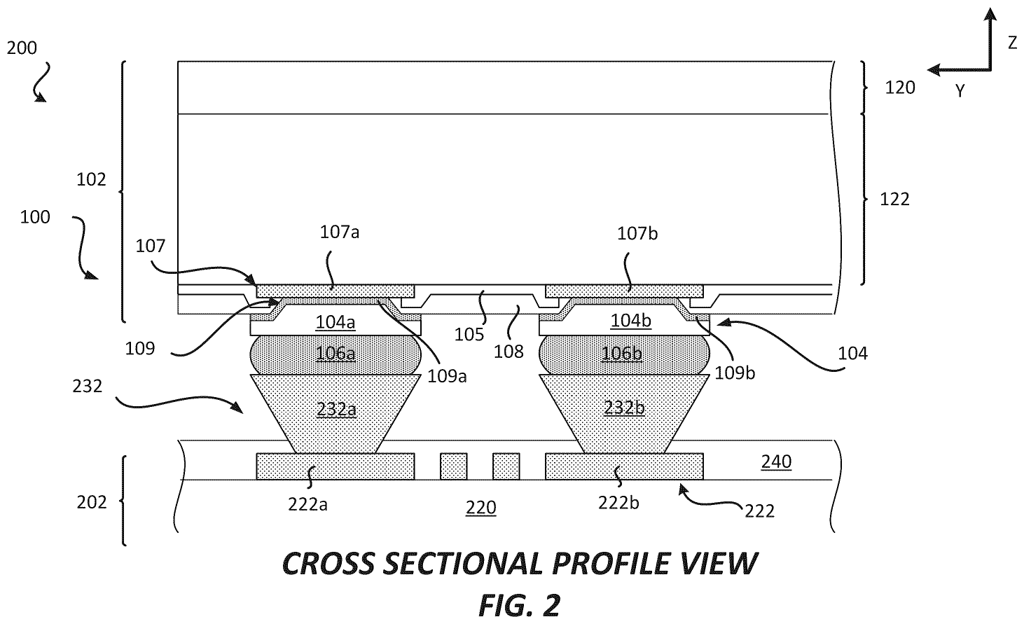

FIG. 2 illustrates a package that includes an integrated device coupled to a substrate comprising post interconnects. FIG. 2 illustrates a package 200 that includes the integrated device 100 and a substrate 202. The substrate 202 includes at least one dielectric layer 220, a plurality of interconnects 222 and a solder resist layer 240. The plurality of interconnects 222 include an interconnect 222a (e.g., first interconnect) and an interconnect 222b (e.g., second interconnect). The interconnect 222a includes a first pad interconnect. The interconnect 222b includes a second pad interconnect.

The plurality of interconnects 222 may include a plurality of post interconnects 232. The plurality of post interconnects 232 include a post interconnect 232a (e.g., first post interconnect) and a post interconnect 232b (e.g., second post interconnect).

The post interconnect 232a includes a profile cross section of a trapezoid shape. In some implementations, the trapezoid shape of the post interconnect 232a is an inverted trapezoid shape, relative to the substrate 202. In some implementations, the trapezoid shape of the post interconnect 232a, includes a first portion and a second portion. The first portion of the trapezoid shape has a first width, and the second portion of the trapezoid shape has a second width. In some implementations, the first portion is a portion of the trapezoid shape that is vertically farthest away from the integrated device 100. In some implementations, the second portion is a portion of the trapezoid shape that is vertically closest to the integrated device 100. In some implementations, the first portion is a portion of the trapezoid shape that is vertically closest to the interconnect 222a of the substrate 202. In some implementations, the second portion is a portion of the trapezoid shape that is vertically farthest away from the interconnect 222a of the substrate 202. In some implementations, the first portion is a portion of the trapezoid shape that is vertically closest to the at least one dielectric layer 220 of the substrate 202. In some implementations, the second portion is a portion of the trapezoid shape that is vertically farthest away from the at least one dielectric layer 220 of the substrate 202.

The post interconnect 232b includes a profile cross section of a trapezoid shape. In some implementations, the trapezoid shape of the post interconnect 232b is an inverted trapezoid shape, relative to the substrate 202. In some implementations, the trapezoid shape of the post interconnect 232b, includes a first portion and a second portion. The first portion of the trapezoid shape has a first width, and the second portion of the trapezoid shape has a second width. In some implementations, the first portion is a portion of the trapezoid shape that is vertically farthest away from the integrated device 100. In some implementations, the second portion is a portion of the trapezoid shape that is vertically closest to the integrated device 100. In some implementations, the first portion is a portion of the trapezoid shape that is vertically closest to the interconnect 222b of the substrate 202. In some implementations, the second portion is a portion of the trapezoid shape that is vertically farthest away from the interconnect 222b of the substrate 202. In some implementations, the first portion is a portion of the trapezoid shape that is vertically closest to the at least one dielectric layer 220 of the substrate 202. In some implementations, the second portion is a portion of the trapezoid shape that is vertically farthest away from the at least one dielectric layer 220 of the substrate 202.

The post interconnect 232a is coupled to the interconnect 222a (e.g., pad interconnect). There may or may not be an interface between the post interconnect 232a and the interconnect 222a. The post interconnect 232b is coupled to the interconnect 222b (e.g., pad interconnect). There may or may not be an interface between the post interconnect 232b and the interconnect 222b.

The integrated device 100 is coupled to the substrate 202 through the plurality of solder interconnects 106 and the plurality of post interconnects 232 such that the plurality of solder interconnects 106 are located between the plurality of post interconnects 232 and the integrated device 100. For example, the solder interconnect 106a may be directly coupled to the post interconnect 232a and the pillar interconnect 104a. In some implementations, the solder interconnect 106a may be coupled to a portion of the post interconnect 232a that has the widest width (e.g., second portion of the trapezoid shape of the profile cross section of the post interconnect 232a). Similarly, the solder interconnect 106b may be directly coupled to the post interconnect 232b and the pillar interconnect 104b. In some implementations, the solder interconnect 106b may be coupled to a portion of the post interconnect 232b that has the widest width (e.g., second portion of the trapezoid shape of the profile cross section of the post interconnect 232b).

In some implementations, the plurality of pillar interconnects 104 may be optional. In such instances, the plurality of solder interconnects 106 may be coupled to the plurality of post interconnects 232 and the plurality of under bump metallization interconnects 109. For example, the solder interconnect 106a may be directly coupled to the post interconnect 232a and the under bump metallization interconnect 109a. Similarly, the solder interconnect 106b may be directly coupled to the post interconnect 232b and the under bump metallization interconnect 109b.

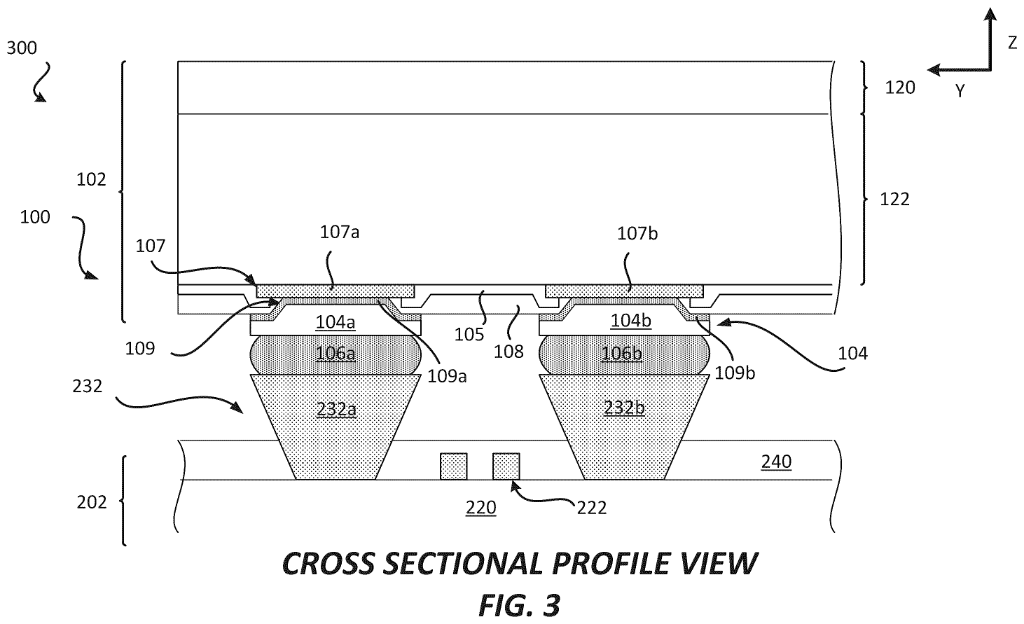

FIG. 3 illustrates a package that includes an integrated device coupled to a substrate comprising post interconnects. FIG. 3 illustrates a package 300 that includes the integrated device 100 and the substrate 202. The substrate 202 of FIG. 3 is similar to the substrate 202 of FIG. 2. The substrate 202 includes at least one dielectric layer 220, a plurality of interconnects 222 and a solder resist layer 240. The plurality of interconnects 222 may include a plurality of post interconnects 232. The plurality of post interconnects 232 include a post interconnect 232a (e.g., first post interconnect) and a post interconnect 232b (e.g., second post interconnect). As shown in FIG. 3, the post interconnect 232a is not directly coupled to a pad (e.g., pad interconnect). Instead, the post interconnect 232a may be directly coupled to a trace interconnect (not visible) from the plurality of interconnects 222. Similarly, the post interconnect 232b is not directly coupled to a pad (e.g., pad interconnect). Instead, the post interconnect 232b may be directly coupled to a trace interconnect (not visible) from the plurality of interconnects 222. The integrated device 100 and the substrate 202 of the package 300 may be coupled together in a similar manner as described for the package 200 described above.

The use of varying widths of the post interconnects helps reduce stress on the dielectric layers of the integrated device 100, which helps reduce the likelihood of delamination of the dielectric layers of the integrated device 100, and thus helps provide a more reliable joint between the integrated device 100 and the substrate 202. Moreover, the more robust and reliable joint helps provide a more reliable electrical path for currents and/or signals traveling between the integrated device 100 and the substrate 202, which can lead to improved performances for the integrated device 100 and the package (e.g., 200, 300). In the configurations shown in FIGS. 2 and 3, the substrate side of the post interconnect has a smaller width than the width of the integrated device side of the post interconnect. This has the effect of reducing the delamination stress on the integrated device, since a higher concentration of the stress may be directed on the substrate side of the plurality of post interconnects. Moreover, implementing post interconnects with trapezoid profile shapes (or inverted trapezoid profile shapes) allows the pitch and/or width of the post interconnects, to be reduced while still reducing the stress on the integrated device 100. In some implementations, a post interconnect may have a minimum width of about 60 micrometers for the widest portion of the post interconnect. In some implementations, a post interconnect may have a minimum width of about 40 micrometers for the narrowest portion of the post interconnect. Thus, in some implementations, a post interconnect may have varying widths with a minimum width in a range of about 40-60 micrometers.

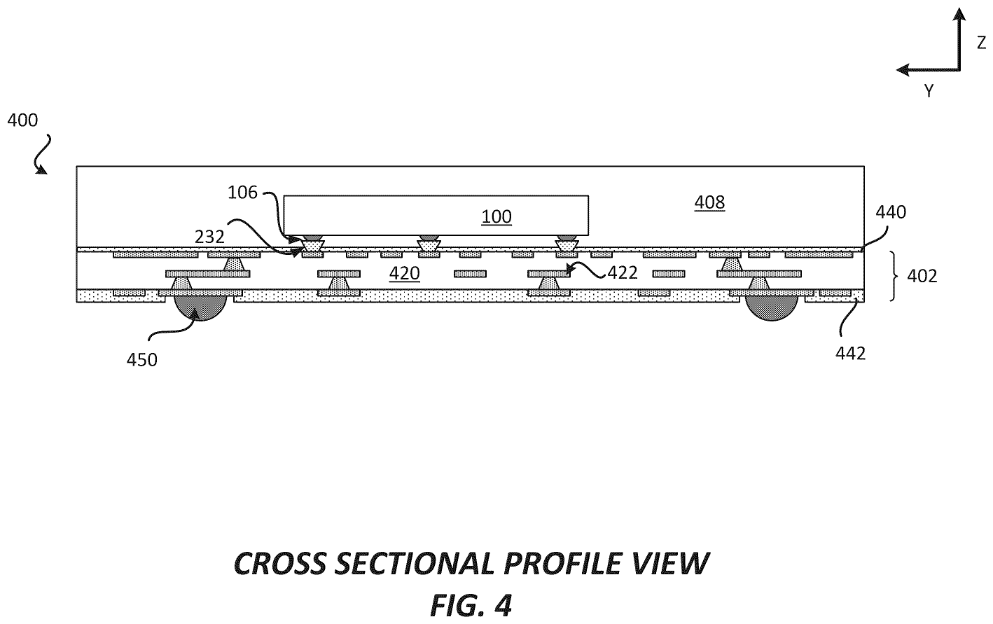

FIG. 4 illustrates a package 400 that includes a substrate 402, the integrated device 100, an encapsulation layer 408 and a plurality of solder interconnects 450. The substrate 402 may be similar to and/or illustrate the substrate 202. The substrate 402 may be an embedded trace substrate (ETS). The substrate 402 includes at least one dielectric layer 420, a plurality of interconnects 422, a solder resist layer 440 and a solder resist layer 442. The plurality of interconnects 422 may include a plurality of post interconnects 232. The plurality of post interconnects 232 of the substrate 402 may be similar and/or identical to the plurality of post interconnects 232 from the substrate 202 of the package 200 and/or the substrate 202 of the package 300. The integrated device 100 is coupled to a first surface (e.g., top surface) of the substrate 402 through the plurality of solder interconnects 106 and the plurality of post interconnects 232. The encapsulation layer 408 may be coupled to the substrate 402 and the integrated device 100. The encapsulation layer 408 may encapsulate the integrated device 100. The encapsulation layer 408 may be located over the substrate 402 and the integrated device 100. The encapsulation layer 408 may include a mold, a resin and/or an epoxy. The encapsulation layer 408 may be a means for encapsulation. The encapsulation layer 408 may be provided by using a compression and transfer molding process, a sheet molding process, or a liquid molding process. A plurality of solder interconnects 450 may be coupled to a second surface (e.g., bottom surface) of the substrate 402. For example, the plurality of solder interconnects 450 may be coupled to the plurality of interconnects 422. FIG. 4 illustrates that the plurality of post interconnects 232 are coupled to pad interconnects. However, as mentioned above in FIG. 3, the plurality of post interconnects 232 may be directly coupled to trace interconnects of the substrate 402. In some implementations, some post interconnects from the plurality of post interconnects 232 may be directly coupled to trace interconnects of the substrate 402, and some post interconnects from the plurality of post interconnects 232 may be directly coupled to pad interconnects of the substrate 402.

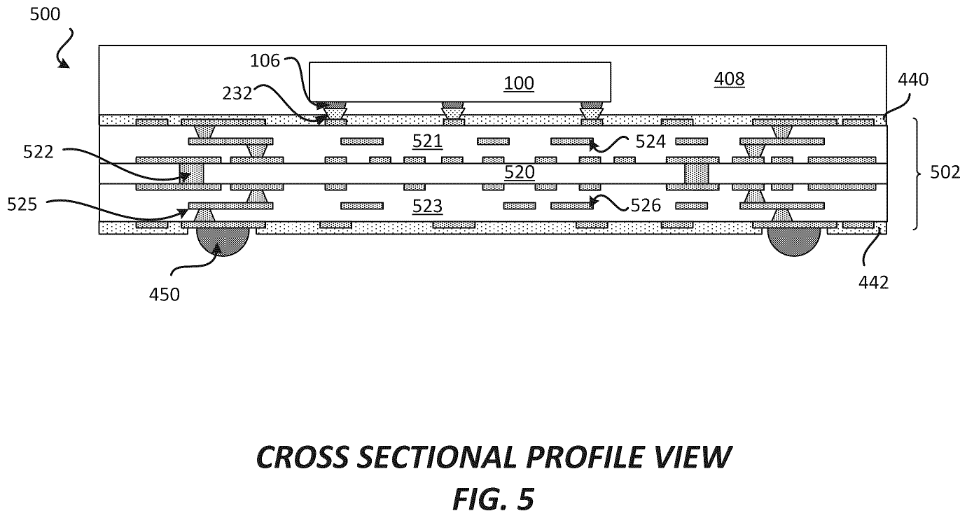

FIG. 5 illustrates a package 500 that includes a substrate 502, the integrated device 100, the encapsulation layer 408 and the plurality of solder interconnects 450. The substrate 502 may be similar to and/or illustrate the substrate 202. The substrate 502 may be a cored substrate. The substrate 502 includes a core layer 520, at least one dielectric layer 521, at least one dielectric layer 523, a plurality of interconnects 525, a solder resist layer 440 and a solder resist layer 442. The plurality of interconnects 525 may include a plurality of core interconnects 522, a plurality of interconnects 524 and a plurality of interconnects 526. The plurality of interconnects 525 may include a plurality of post interconnects 232. The plurality of post interconnects 232 of the substrate 502 may be similar and/or identical to the plurality of post interconnects 232 from the substrate 202 of the package 200 and/or the substrate 202 of the package 300.

The integrated device 100 is coupled to a first surface (e.g., top surface) of the substrate 502 through the plurality of solder interconnects 106 and the plurality of post interconnects 232. The encapsulation layer 408 may be coupled to the substrate 502 and the integrated device 100. The encapsulation layer 408 may encapsulate the integrated device 100. The encapsulation layer 408 may be located over the substrate 502 and the integrated device 100. The encapsulation layer 408 may include a mold, a resin and/or an epoxy. The encapsulation layer 408 may be a means for encapsulation. The encapsulation layer 408 may be provided by using a compression and transfer molding process, a sheet molding process, or a liquid molding process.

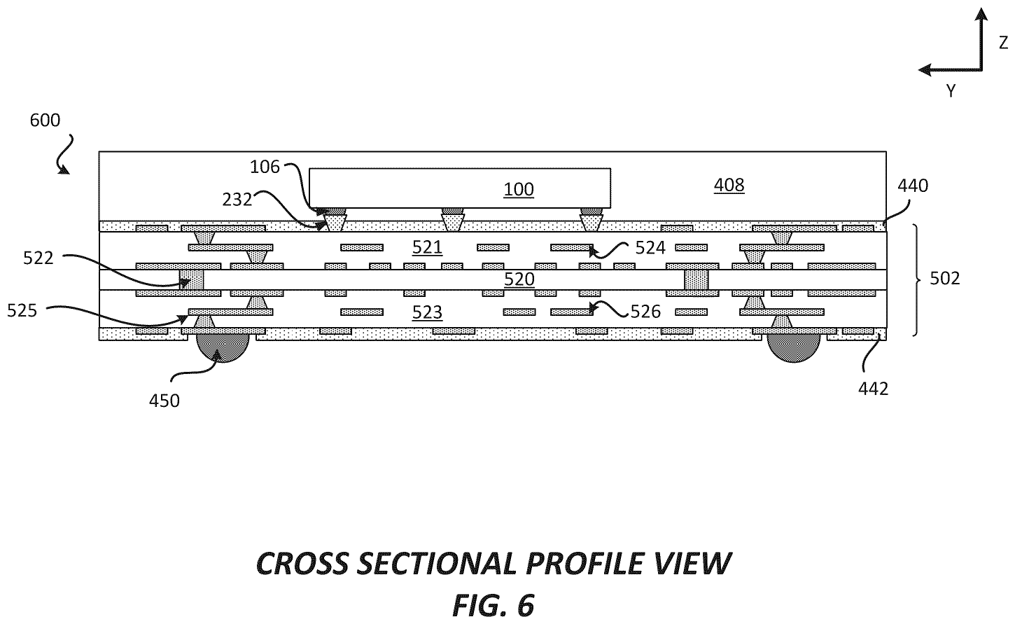

FIG. 6 illustrates a package 600 that includes a substrate 502, the integrated device 100, the encapsulation layer 408 and the plurality of solder interconnects 450. The package 600, the integrated device 100 and the substrate 502 of FIG. 6 are similar to the package 500, the integrated device 100 and the substrate 502 of FIG. 5. However, in FIG. 6, the plurality of post interconnects 232 are not directly coupled to pad interconnects. Instead, the plurality of post interconnects 232 are directly coupled to trace interconnects of the substrate 502. In some implementations, some post interconnects from the plurality of post interconnects 232 may be directly coupled to trace interconnects of the substrate 502, and some post interconnects from the plurality of post interconnects 232 may be directly coupled to pad interconnects of the substrate 502.

An integrated device (e.g., 100) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device (e.g., 100) may include at least one electronic circuit (e.g., first electronic circuit, second electronic circuit, etc. . . . ). An integrated device may include transistors. An integrated device may be an example of an electrical component and/or electrical device. In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device (e.g., 100) may be fabricated using a first technology node, and a chiplet may be fabricated using a second technology node that is not as advanced as the first technology node. In such an example, the integrated device (e.g., 100) may include components (e.g., interconnects, transistors) that have a first minimum size, and the chiplet may include components (e.g., interconnects, transistors) that have a second minimum size, where the second minimum size is greater than the first minimum size. In some implementations, an integrated device and another integrated device of a package, may be fabricated using the same technology node or different technology nodes. In some implementations, a chiplet and another chiplet of a package, may be fabricated using the same technology node or different technology nodes.

### Exemplary Sequence for Fabricating an Substrate Comprising a Post Interconnect

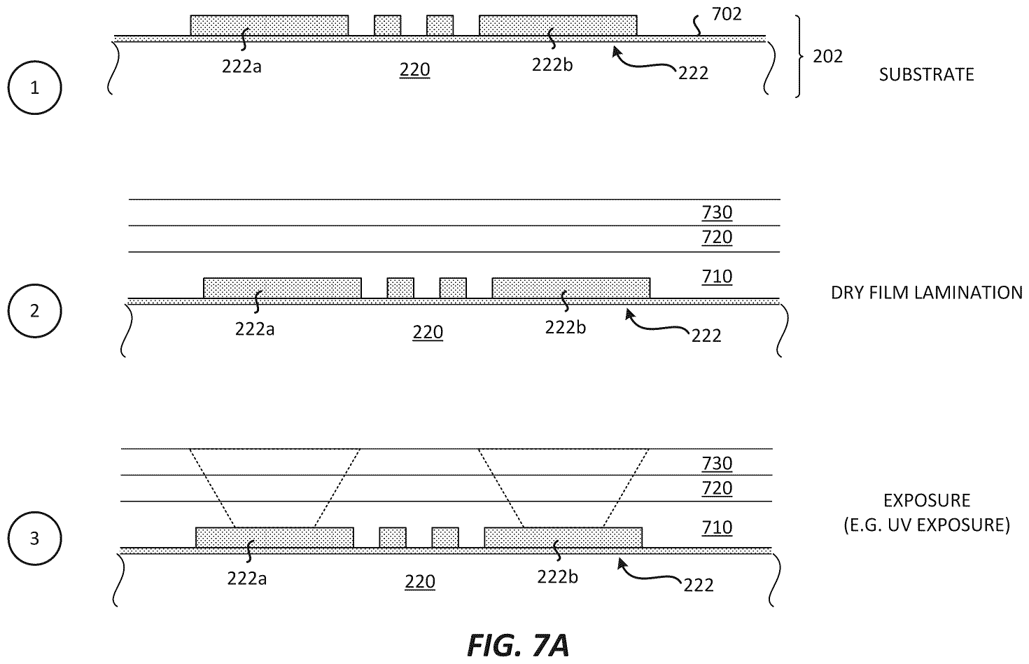

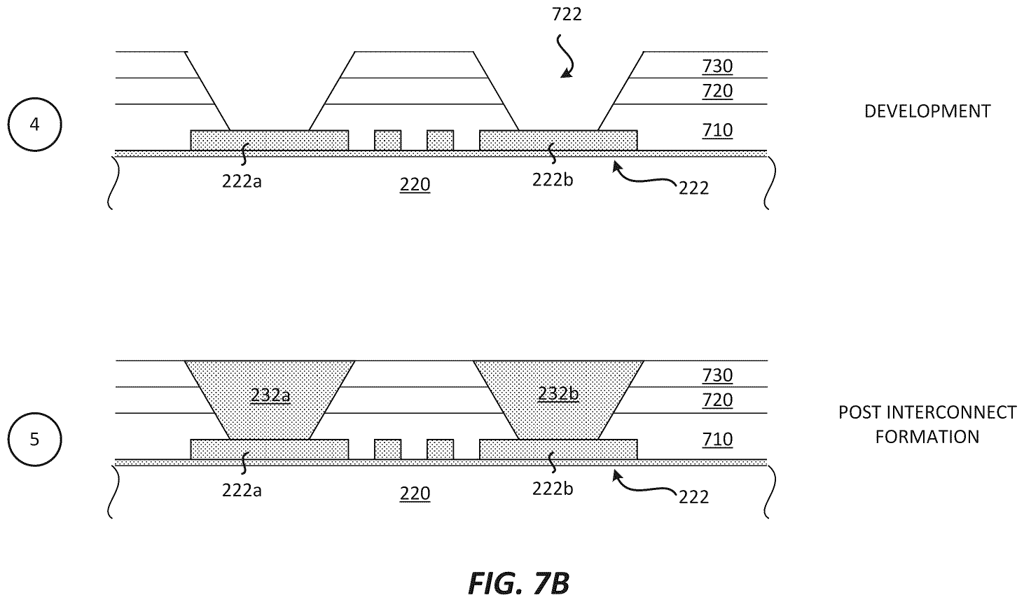

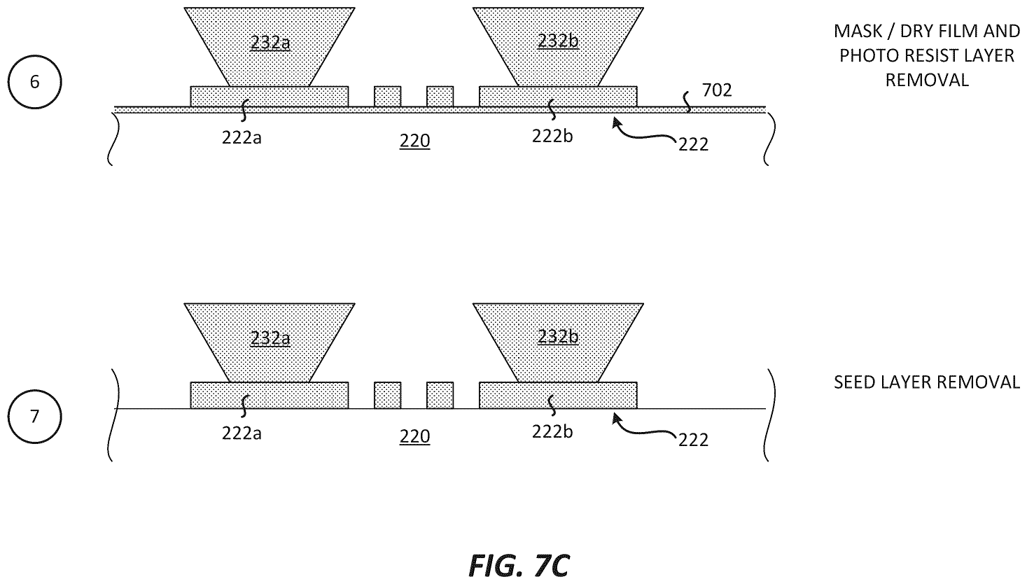

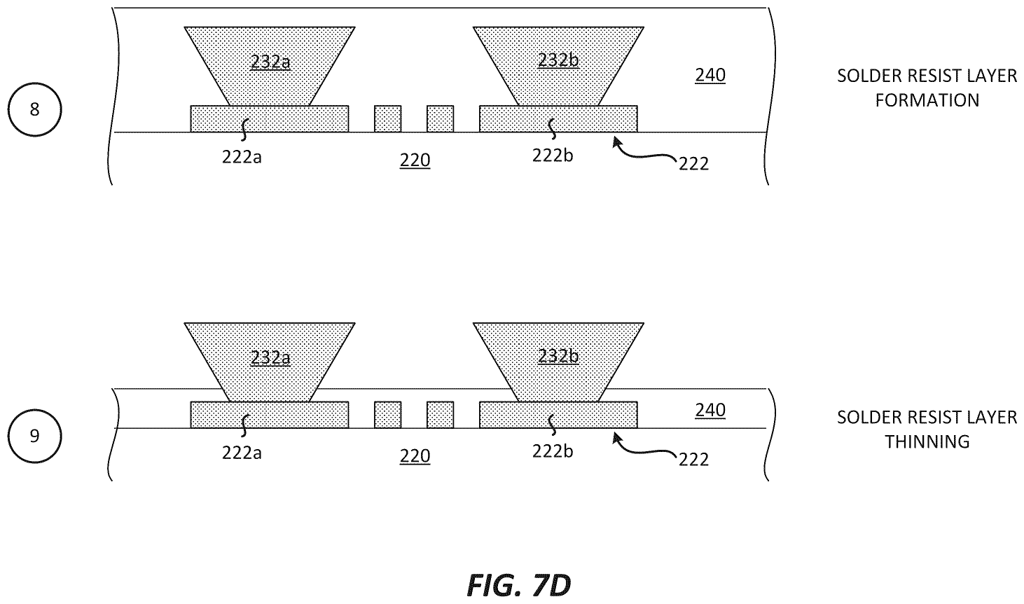

In some implementations, fabricating a substrate includes several processes. FIGS. 7A-7D illustrate an exemplary sequence for providing or fabricating a substrate comprising post interconnects with varying widths. In some implementations, the sequence of FIGS. 7A-7D may be used to provide or fabricate the substrate 202 of FIG. 2. However, the process of FIGS. 7A-7D may be used to fabricate any of the substrates described in the disclosure.

It should be noted that the sequence of FIGS. 7A-7D may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

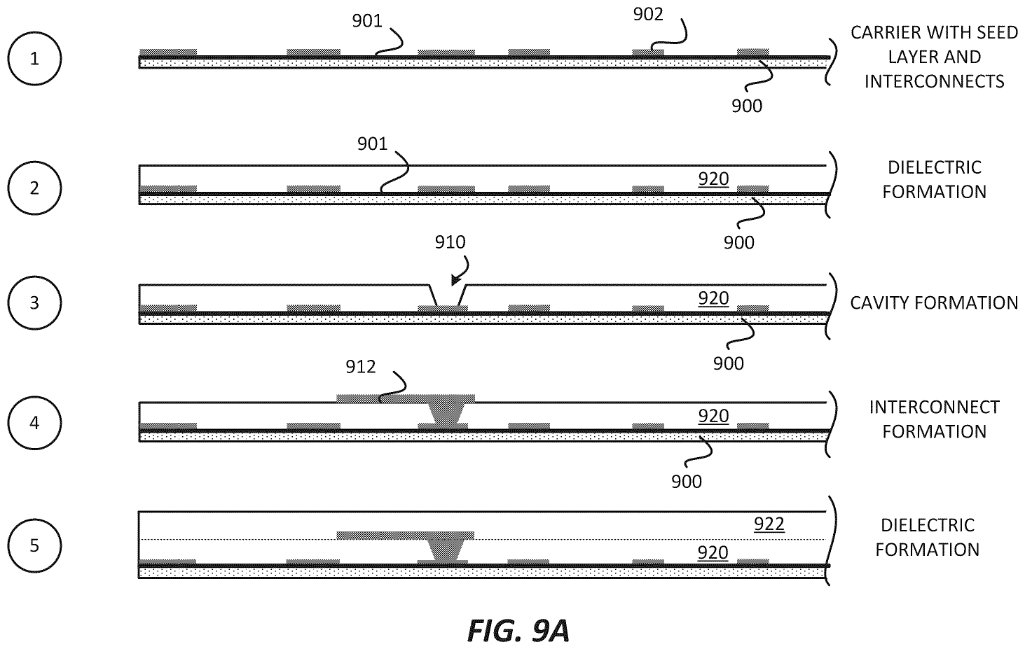

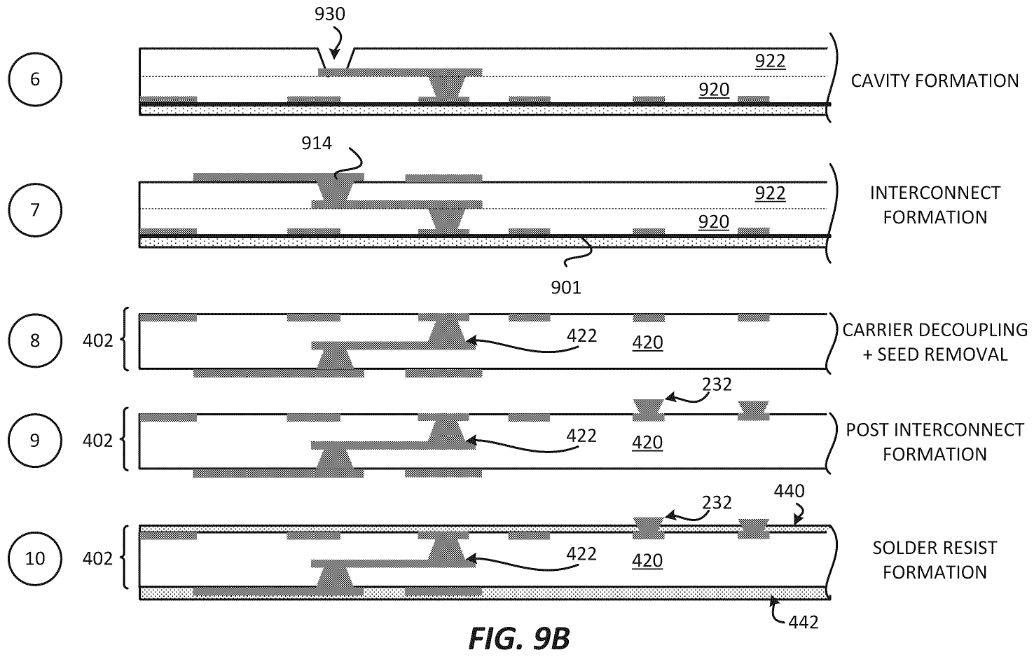

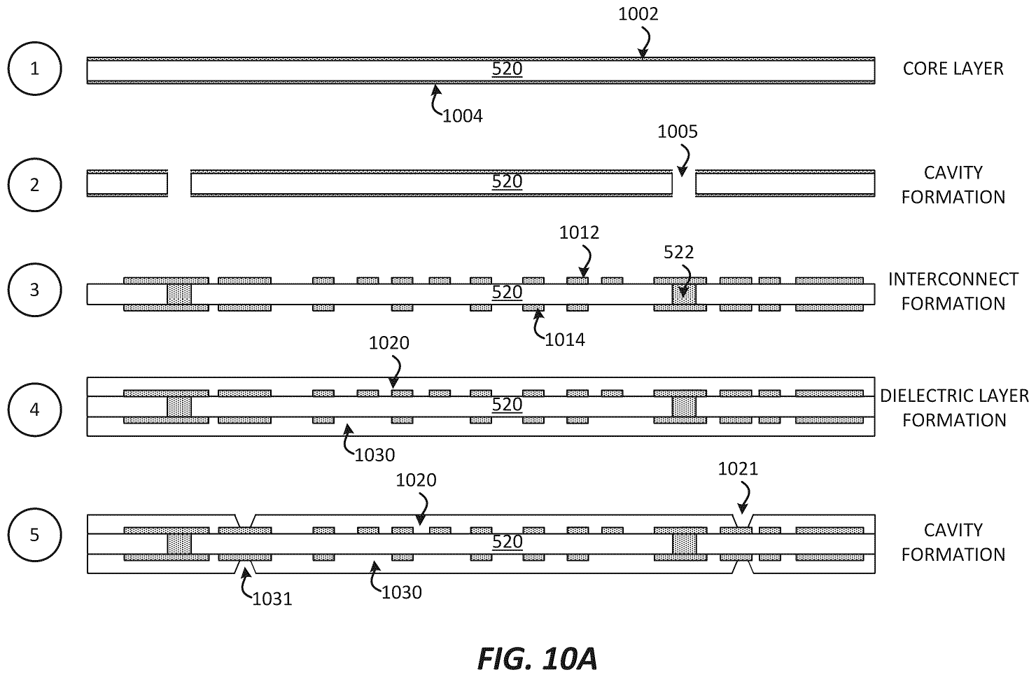

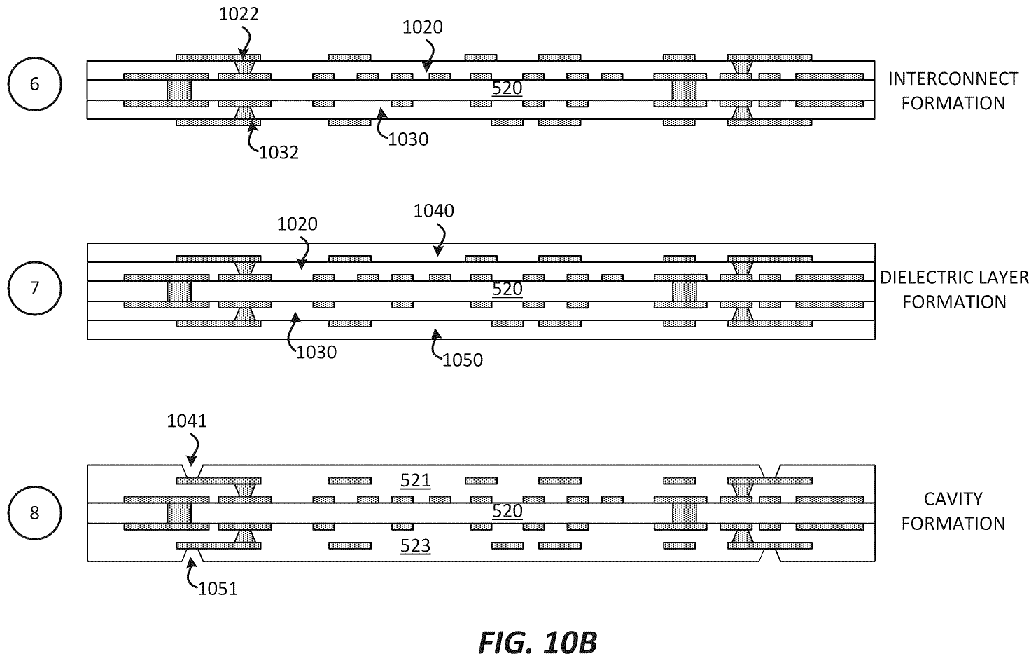

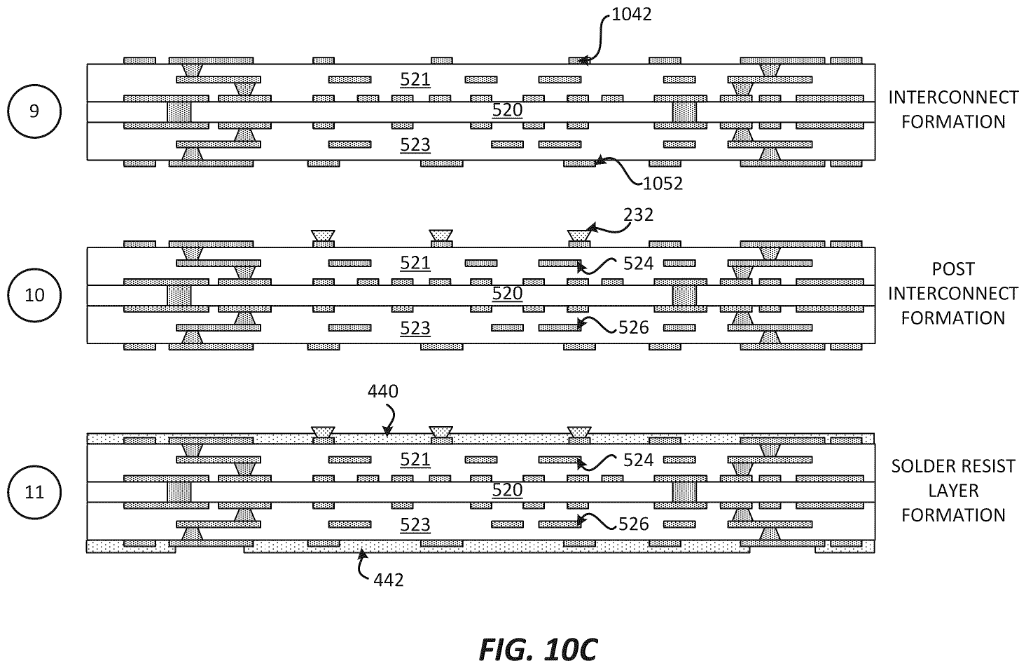

Stage 1, as shown in FIG. 7A, illustrates a state after a substrate 202 is provided. The substrate 202 includes at least one dielectric layer 220, a seed layer 702, and a plurality of interconnects 222. The plurality of interconnects 222 include an interconnect 222a and an interconnect 222b. The substrate 202 may represent the substrate 402 or the substrate 502. The substrate 202 may be fabricated using a process as described in FIGS. 9A-9B or a process as described in FIGS. 10A-10C.

Stage 2 illustrates a state after a first photo resist layer 710 is formed over the substrate 202. For example, the first photo resist layer 710 may be formed over the seed layer 702, the interconnect 222a and the interconnect 222b. The first photo resist layer 710 may be a first dry film layer. A lamination process may be used to form the first photo resist layer 710. Stage 2 also illustrates a state after a second photo resist layer 720 is formed over the first photo resist layer 710. The second photo resist layer 720 may be a second dry film layer. A lamination process may be used to form the second photo resist layer 720. Stage 2 further illustrates a state after a third photo resist layer 730 is formed over the second photo resist layer 720. The third photo resist layer 730 may be a third dry film layer. A lamination process may be used to form the third photo resist layer 730.

The first photo resist layer 710, the second photo resist layer 720 and the third photo resist layer 730 may include a positive photo resist layer. However, in some implementations, the first photo resist layer 710, the second photo resist layer 720 and the third photo resist layer 730 may include a negative photo resist layer.

The first photo resist layer 710, the second photo resist layer 720 and the third photo resist layer 730 may have different photo properties. For example, the first photo resist layer 710, the second photo resist layer 720 and the third photo resist layer 730 may have different sensitivities to light. In some implementations, the third photo resist layer 730 may be more photo sensitive to light than the second photo resist layer 720 and the first photo resist layer 710. In some implementations, the second photo resist layer 720 may be more photo sensitive to light than the first photo resist layer 710. However, different implementations may use photo resist layers with different configurations of light sensitivities and/or light resistivities. Moreover, different implementations may use different numbers of photo resist layers. Thus, different implementations may use more or less than three photo resist layers. The first photo resist layer 710, the second photo resist layer 720 and the third photo resist layer 730 may have similar thicknesses or different thicknesses.

Stage 3 illustrates a state after the photo resist layers have been exposed to light. A masking process and an exposure process that are part of a photolithography process be used to expose the photo resist layers. The trapezoid shapes that are shown at Stage 3 illustrate how the expose to light may affect the various photo resist layers. In this example, the third photo resist layer 730 is most sensitive to light, which produces a portion of the third photo resist layer 730 that is affected by the light to have the greatest width. The second photo resist layer 720 is not as sensitive to light than the third photo resist layer 730, and as such the portion of the second photo resist layer 720 has a width that is less than the width of the portion of the third photo resist layer 730 that is affected by the light. The first photo resist layer 710 is not as sensitive to light than the third photo resist layer 730 and the second photo resist layer, and as such the portion of the first photo resist layer 710 has a width that is less than the width of the portion of the third photo resist layer 730 that is affected by the light and the width of the portion of the second photo resist layer 720 that is affected by the light. A portion of a photo resist layer that is exposed to light may breakdown and may be removed. In some implementations, a portion of a photo resist layer that is exposed may harden and/or cure, leaving the un-exposed portion of the photo resist layer to be removed.

Stage 4 of FIG. 7B, illustrates a state after portions of the first photo resist layer 710, the second photo resist layer 720 and the third photo resist layer 730 are removed, forming a plurality of openings 722 in the first photo resist layer 710, the second photo resist layer 720 and the third photo resist layer 730. A development process and/or rinsing process may remove portions of the first photo resist layer 710, the second photo resist layer 720 and the third photo resist layer 730. Portions of the first photo resist layer 710, the second photo resist layer 720 and the third photo resist layer 730 that are removed may be portions that have been exposed to light. The plurality of openings 722 may have a profile cross section of a trapezoid shape or an inverted trapezoid shape. The plurality of openings 722 may have diagonal walls (e.g., relative to a surface of the at least one dielectric layer 220, relative to a surface of an interconnect (e.g., 222a)).

Stage 5 illustrates a state after a plurality of post interconnects 232 are formed through the plurality of openings 722 of the first photo resist layer 710, the second photo resist layer 720 and the third photo resist layer 730. The plurality of post interconnects 232 include the post interconnect 232a and the post interconnect 232b. The plurality of post interconnects 232 may be formed over and coupled to the interconnect 222a (e.g., pad interconnect) and the interconnect 222b (e.g., pad interconnect). A masking and a plating process may be used to form the plurality of post interconnects 232. The plurality of post interconnects 232 may include a side profile cross section that includes the shape of a trapezoid. For example, a top portion of a post interconnect may have a greater width (e.g., diameter) than a bottom portion of the post interconnect. The plurality of post interconnects 232 may have a diagonal surface.

Stage 6, as shown in FIG. 7C, illustrates a state after the first photo resist layer 710, the second photo resist layer 720 and the third photo resist layer 730 are removed. The first photo resist layer 710, the second photo resist layer 720 and the third photo resist layer 730 may be removed through a development process. The first photo resist layer 710, the second photo resist layer 720 and the third photo resist layer 730 may be removed through a rinsing process. A mask that may have been used may also be removed.

Stage 7 illustrates a state after portions of the seed layer 702 are removed. An etching process may be used to remove portions of the seed layer 702. Any remaining seed layer 702 may be considered part of an interconnect (e.g., 222a, 222b) of the substrate 202.

Stage 8 of FIG. 7D, illustrates a state after a solder resist layer 240 is formed over the at least one dielectric layer 220 and the plurality of post interconnects 232. A lamination process and/or a deposition process may be used to form the solder resist layer 240.

Stage 9 illustrates a state after the solder resist layer 240 is thinned so that the outer surface of the solder resist layer 240 is lower than a top surface of the plurality of post interconnects 232.

### Exemplary Sequence for Fabricating an Substrate Comprising a Post Interconnect

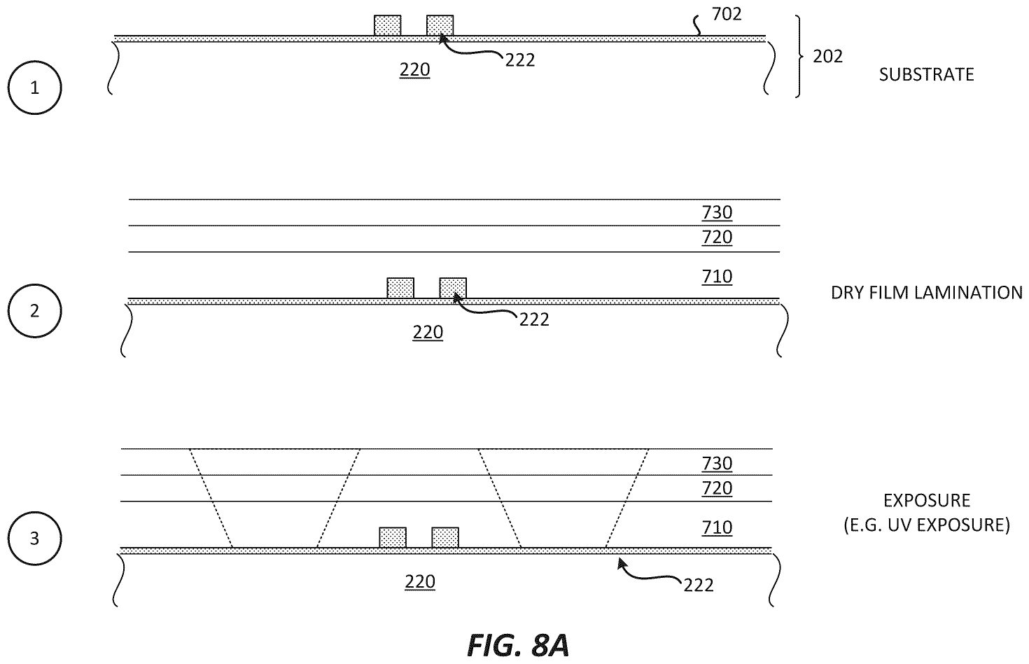

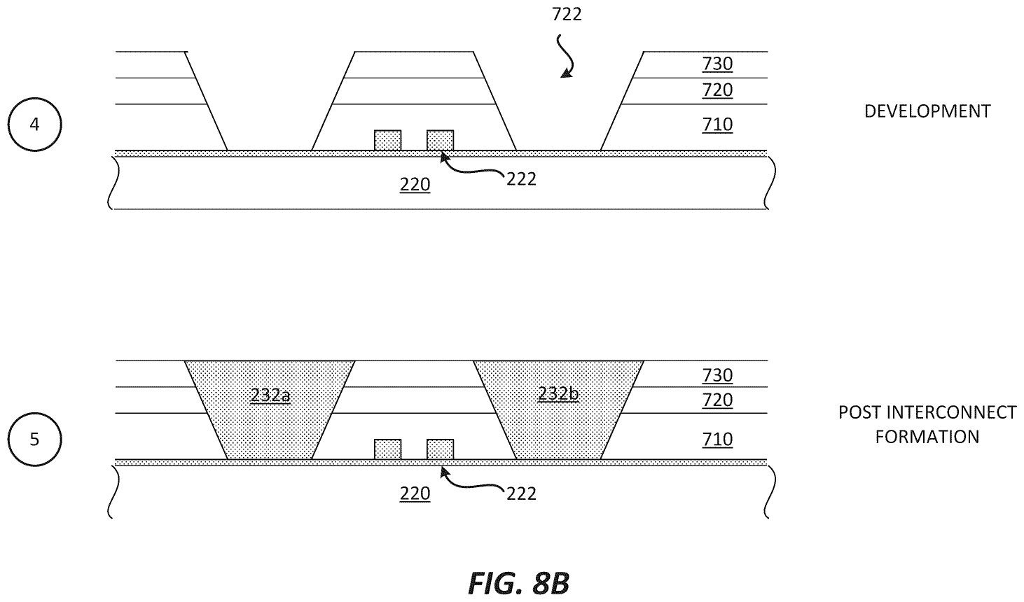

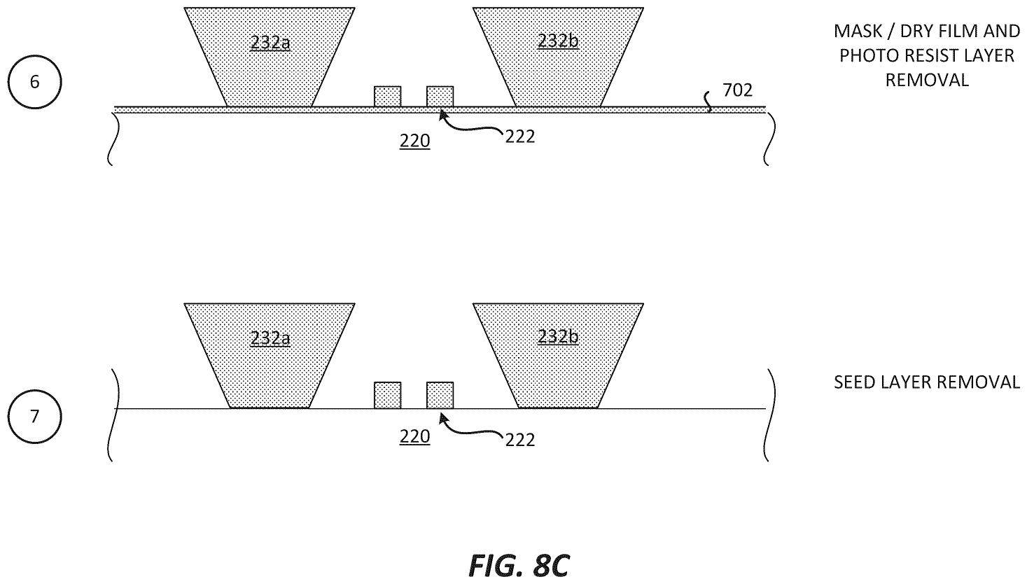

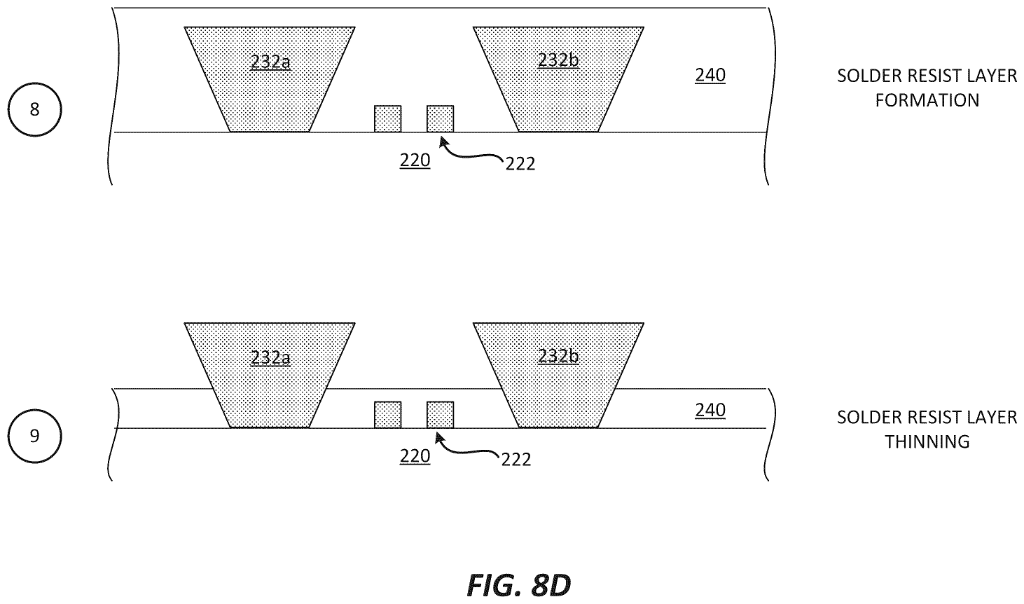

In some implementations, fabricating a substrate includes several processes. FIGS. 8A-8D illustrate an exemplary sequence for providing or fabricating a substrate comprising post interconnects with varying widths. In some implementations, the sequence of FIGS. 8A-8D may be used to provide or fabricate the substrate 202 of FIG. 3. However, the process of FIGS. 8A-8D may be used to fabricate any of the substrates described in the disclosure.

It should be noted that the sequence of FIGS. 8A-8D may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 8A, illustrates a state after a substrate 202 is provided. The substrate 202 includes at least one dielectric layer 220, a seed layer 702, and a plurality of interconnects 222. The substrate 202 may represent the substrate 402 or the substrate 502. The substrate 202 may be fabricated using a process as described in FIGS. 9A-9B or a process as described in FIGS. 10A-10C.

Stage 2 illustrates a state after a first photo resist layer 710 is formed over the substrate 202. For example, the first photo resist layer 710 may be formed over the seed layer 702 and the plurality of interconnects 222. The first photo resist layer 710 may be a first dry film layer. A lamination process may be used to form the first photo resist layer 710. Stage 2 also illustrates a state after a second photo resist layer 720 is formed over the first photo resist layer 710. The second photo resist layer 720 may be a second dry film layer. A lamination process may be used to form the second photo resist layer 720. Stage 2 further illustrates a state after a third photo resist layer 730 is formed over the second photo resist layer 720. The third photo resist layer 730 may be a third dry film layer. A lamination process may be used to form the third photo resist layer 730.

The first photo resist layer 710, the second photo resist layer 720 and the third photo resist layer 730 may include a positive photo resist layer. However, in some implementations, the first photo resist layer 710, the second photo resist layer 720 and the third photo resist layer 730 may include a negative photo resist layer.

The first photo resist layer 710, the second photo resist layer 720 and the third photo resist layer 730 may have different photo properties. For example, the first photo resist layer 710, the second photo resist layer 720 and the third photo resist layer 730 may have different sensitivities to light. In some implementations, the third photo resist layer 730 may be more photo sensitive to light than the second photo resist layer 720 and the first photo resist layer 710. In some implementations, the second photo resist layer 720 may be more photo sensitive to light than the first photo resist layer 710. However, different implementations may use photo resist layers with different configurations of light sensitivities and/or light resistivities. Moreover, different implementations may use different numbers of photo resist layers. Thus, different implementations may use more or less than three photo resist layers. The first photo resist layer 710, the second photo resist layer 720 and the third photo resist layer 730 may have similar thicknesses or different thicknesses.

Stage 3 illustrates a state after the photo resist layers have been exposed to light. A masking process and an exposure process that are part of a photolithography process be used to expose the photo resist layers. The trapezoid shapes that are shown at Stage 3 illustrate how the expose to light may affect the various photo resist layers. In this example, the third photo resist layer 730 is most sensitive to light, which produces a portion of the third photo resist layer 730 that is affected by the light to have the greatest width. The second photo resist layer 720 is not as sensitive to light than the third photo resist layer 730, and as such the portion of the second photo resist layer 720 has a width that is less than the width of the portion of the third photo resist layer 730 that is affected by the light. The first photo resist layer 710 is not as sensitive to light than the third photo resist layer 730 and the second photo resist layer, and as such the portion of the first photo resist layer 710 has a width that is less than the width of the portion of the third photo resist layer 730 that is affected by the light and the width of the portion of the second photo resist layer 720 that is affected by the light. A portion of a photo resist layer that is exposed to light may breakdown and may be removed. In some implementations, a portion of a photo resist layer that is exposed may harden and/or cure, leaving the un-exposed portion of the photo resist layer to be removed.

Stage 4 of FIG. 8B, illustrates a state after portions of the first photo resist layer 710, the second photo resist layer 720 and the third photo resist layer 730 to be removed, forming a plurality of openings 722 in the first photo resist layer 710, the second photo resist layer 720 and the third photo resist layer 730. A development process and/or rinsing process may remove portions of the first photo resist layer 710, the second photo resist layer 720 and the third photo resist layer 730. Portions of the first photo resist layer 710, the second photo resist layer 720 and the third photo resist layer 730 that are removed may be portions that have been exposed to light. The plurality of openings 722 may have a profile cross section of a trapezoid shape or an inverted trapezoid shape. The plurality of openings 722 may have diagonal walls (e.g., relative to a surface of the at least one dielectric layer 220, relative to a surface of the seed layer 702).

Stage 5 illustrates a state after a plurality of post interconnects 232 are formed through the plurality of openings 722 of the first photo resist layer 710, the second photo resist layer 720 and the third photo resist layer 730. The plurality of post interconnects 232 include the post interconnect 232a and the post interconnect 232b. The plurality of post interconnects 232 may be formed over the seed layer 702. A masking and a plating process may be used to form the plurality of post interconnects 232. The plurality of post interconnects 232 may include a side profile cross section that includes the shape of a trapezoid. For example, a top portion of a post interconnect may have a greater width (e.g., diameter) than a bottom portion of the post interconnect. The plurality of post interconnects 232 may have a diagonal surface. The plurality of post interconnects 232 are not directly coupled to pad interconnects of the substrate 202. However, the plurality of post interconnects 232 may be directly coupled to trace interconnects of the substrate 202.

Stage 6, as shown in FIG. 8C, illustrates a state after the first photo resist layer 710, the second photo resist layer 720 and the third photo resist layer 730 are removed. The first photo resist layer 710, the second photo resist layer 720 and the third photo resist layer 730 may be removed through a development process. The first photo resist layer 710, the second photo resist layer 720 and the third photo resist layer 730 may be removed through a rinsing process. A mask that may have been used may also be removed.

Stage 7 illustrates a state after portions of the seed layer 702 are removed. An etching process may be used to remove portions of the seed layer 702. Any remaining seed layer 702 may be considered part of an interconnect from the plurality of interconnects 222 and/or a post interconnect (e.g., 232a, 232b) of the substrate 202.

Stage 8 of FIG. 8D, illustrates a state after a solder resist layer 240 is formed over the at least one dielectric layer 220 and the plurality of post interconnects 232. A lamination process and/or a deposition process may be used to form the solder resist layer 240.

Stage 9 illustrates a state after the solder resist layer 240 is thinned so that the outer surface of the solder resist layer 240 is lower than a top surface of the plurality of post interconnects 232.

### Exemplary Sequence for Fabricating a Substrate

In some implementations, fabricating a substrate includes several processes. FIGS. 9A-9B illustrate an exemplary sequence for providing or fabricating a substrate. In some implementations, the sequence of FIGS. 9A-9B may be used to provide or fabricate the substrate 402. However, the process of FIGS. 9A-9B may be used to fabricate any of the substrates described in the disclosure.

It should be noted that the sequence of FIGS. 9A-9B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 9A, illustrates a state after a carrier 900 is provided. A seed layer 901 and interconnects 902 may be located over the carrier 900. The interconnects 902 may be located over the seed layer 901. A plating process and etching process may be used to form the interconnects 902. In some implementations, the carrier 900 may be provided with the seed layer 901 and a metal layer that is patterned to form the interconnects 902. The interconnects 902 may represent at least some of the interconnects from the plurality of interconnects 422.

Stage 2 illustrates a state after a dielectric layer 920 is formed over the carrier 900, the seed layer 901 and the interconnects 902. A deposition and/or lamination process may be used to form the dielectric layer 920. The dielectric layer 920 may include prepreg and/or polyimide. The dielectric layer 920 may include a photo-imageable dielectric. However, different implementations may use different materials for the dielectric layer.

Stage 3 illustrates a state after a plurality of cavities 910 is formed in the dielectric layer 920. The plurality of cavities 910 may be formed using an etching process (e.g., photo etching process) or laser process.

Stage 4 illustrates a state after interconnects 912 are formed in and over the dielectric layer 920, including in and over the plurality of cavities 910. For example, a via, pad and/or traces may be formed. A plating process may be used to form the interconnects.

Stage 5 illustrates a state after a dielectric layer 922 is formed over the dielectric layer 920 and the interconnects 912. A deposition and/or lamination process may be used to form the dielectric layer 922. The dielectric layer 922 may include prepreg and/or polyimide. The dielectric layer 922 may include a photo-imageable dielectric. However, different implementations may use different materials for the dielectric layer.

Stage 6, as shown in FIG. 9B, illustrates a state after a plurality of cavities 930 is formed in the dielectric layer 922. The plurality of cavities 930 may be formed using an etching process (e.g., photo etching process) or laser process.

Stage 7 illustrates a state after interconnects 914 are formed in and over the dielectric layer 922, including in and over the plurality of cavities 930. For example, a via, pad and/or traces may be formed. A plating process may be used to form the interconnects.

Stage 8 illustrates a state after the carrier 900 is decoupled (e.g., detached, removed, grinded out) from at least one dielectric layer 920 and the seed layer 901, portions of the seed layer 901 are removed (e.g., etched out), leaving the substrate 402 that includes at least one dielectric layer 420 and the plurality of interconnects 422. The at least one dielectric layer 420 may represent the dielectric layer 920 and/or the dielectric layer 922. The plurality of interconnects 422 may represent the interconnects 902, 912 and/or 914.

Stage 9 illustrates a state after a plurality of post interconnects 232 are formed. In some implementations, the plurality of post interconnects 232 may be formed in a manner as described in FIGS. 7A-7D and/or FIGS. 8A-8D. The plurality of post interconnects 232 may be coupled to the plurality of interconnects 422. The plurality of post interconnects 232 may be considered part of the plurality of interconnects 422.

Stage 10 illustrates a state after a solder resist layer 440 and a solder resist layer 442 are formed. A lamination process and/or a deposition process may be used to form the solder resist layer 440 and the solder resist layer 442.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Substrate

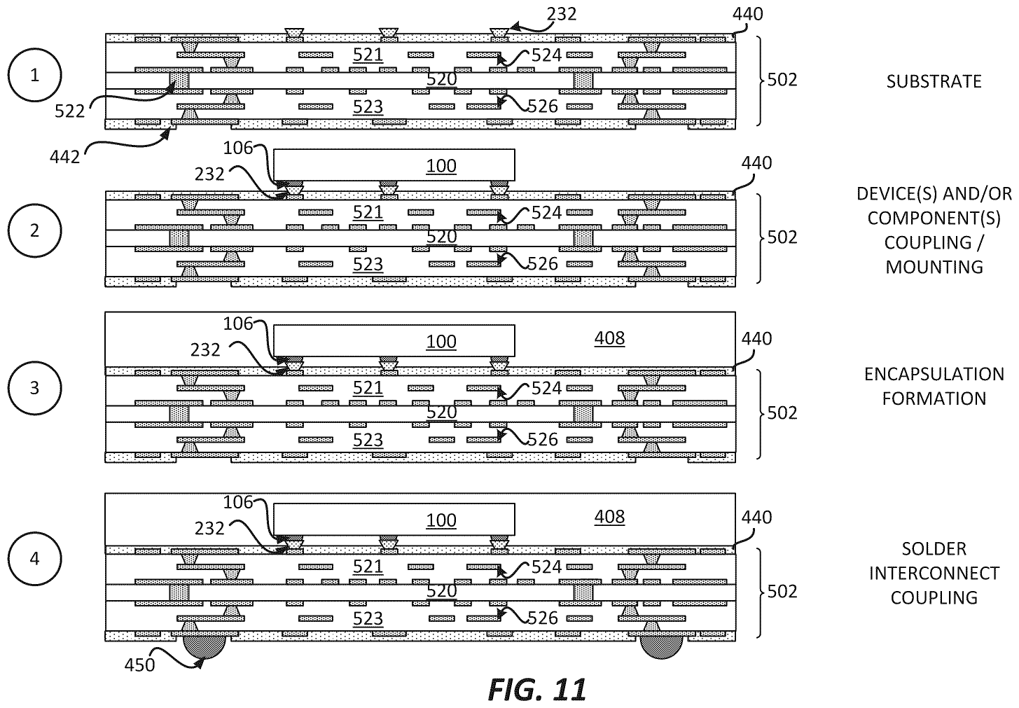

In some implementations, fabricating a substrate includes several processes. FIGS. 10A-10C illustrate an exemplary sequence for providing or fabricating a substrate. In some implementations, the sequence of FIGS. 10A-10C may be used to provide or fabricate the substrate 502. However, the process of FIGS. 10A-11C may be used to fabricate any of the substrates described in the disclosure.

It should be noted that the sequence of FIGS. 10A-10C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 10A, illustrates a state after a core layer 520 is provided. The core layer 520 may include a seed layer 1002 located on a first surface of the core layer 520 and a seed layer 1004 located on a second surface of the core layer 520. The core layer 520 may be a dielectric.

Stage 2 illustrates a state after a plurality of cavities 1005 are formed through the core layer 520, the seed layer 1002 and the seed layer 1004. The plurality of cavities 1005 may be formed using an etching process and/or laser process.

Stage 3 illustrates a state after interconnects are formed in and over surfaces of the core layer 520. A plurality of core interconnects 522 may be formed in the plurality of cavities 1005. A plurality of interconnects 1012 may be formed over (e.g., above) a first surface of the core layer 520. The seed layer 1002 may be part of the plurality of interconnects 1012. A plurality of interconnects 1014 may be formed over (e.g., below) a second surface of the core layer 520. The seed layer 1004 may be part of the plurality of interconnects 1014. A masking, a plating and/or an etching process may be used to form the plurality of core interconnects 522, the plurality of interconnects 1012 and/or the plurality of interconnects 1014.

Stage 4 illustrates a state after a dielectric layer 1020 is formed over (e.g., above) the first surface of the core layer 520 and the plurality of interconnects 1012. Stage 4 also illustrates a state after a dielectric layer 1030 is formed over (e.g., below) the second surface of the core layer 520 and the plurality of interconnects 1014. A deposition and/or a lamination process may be used to form the dielectric layer 1020 and the dielectric layer 1030. The dielectric layer 1020 and the dielectric layer 1030 may be a different material than the core layer 520.

Stage 5 illustrates a state after a plurality of cavities 1021 are formed in the dielectric layer 1020 and a plurality of cavities 1031 are formed in the dielectric layer 1030. The plurality of cavities 1021 and the plurality of cavities 1031 may be formed using an etching process (e.g., photo etching process). A masking, an exposure and/or a development process may be used to form the plurality of cavities 1021 and the plurality of cavities 1031.

Stage 6, as shown in FIG. 10B, illustrates a state after interconnects are formed in and over surfaces of the dielectric layer 1020 and the dielectric layer 1030. A plurality of interconnects 1022 may be formed over (e.g., above) a first surface of the dielectric layer 1020 and the plurality of cavities 1021. A plurality of interconnects 1032 may be formed over (e.g., below) a second surface of the dielectric layer 1030 and the plurality of cavities 1031. A masking, a plating and/or an etching process may be used to form the plurality of interconnects 1022 and/or the plurality of interconnects 1032.

Stage 7 illustrates a state after a dielectric layer 1040 is formed over (e.g., above) the first surface of the dielectric layer 1020 and the plurality of interconnects 1022. Stage 7 also illustrates a state after a dielectric layer 1050 is formed over (e.g., below) the second surface of the dielectric layer 1030 and the plurality of interconnects 1032. A deposition and/or a lamination process may be used to form the dielectric layer 1040 and the dielectric layer 1040. The dielectric layer 1040 and/or the dielectric layer 1050 may be the same dielectric layer as the dielectric layer 1020 and/or the dielectric layer 1030.

Stage 8 illustrates a state after a plurality of cavities 1041 are formed in the dielectric layer 1040 and a plurality of cavities 1051 are formed in the dielectric layer 1050. The plurality of cavities 1041 and the plurality of cavities 1051 may be formed using an etching process (e.g., photo etching process). A masking, an exposure and/or a development process may be used to form the plurality of cavities 1041 and the plurality of cavities 1051. The at least one dielectric layer 521 may represent the dielectric layer 1020 and/or the dielectric layer 1040. The at least one dielectric layer 523 may represent the dielectric layer 1030 and/or the dielectric layer 1050.

Stage 9, as shown in FIG. 10C, illustrates a state after interconnects are formed in and over surfaces of the dielectric layer 1040 and the dielectric layer 1050. A plurality of interconnects 1042 may be formed over (e.g., above) a first surface of the dielectric layer 1040 and the plurality of cavities 1041. A plurality of interconnects 1052 may be formed over (e.g., below) a second surface of the dielectric layer 1050 and the plurality of cavities 1051. A masking, a plating and/or an etching process may be used to form the plurality of interconnects 1042 and/or the plurality of interconnects 1052. The plurality of interconnects 1022 and/or the plurality of interconnects 1042 may be represented by a plurality of interconnects 524, as shown at stage 10. The plurality of interconnects 1032 and/or the plurality of interconnects 1052 may be represented by a plurality of interconnects 526, as shown at stage 10.

Stage 10 illustrates a state after a plurality of post interconnects 232 are formed. In some implementations, the plurality of post interconnects 232 may be formed in a manner as described in FIGS. 7A-7D and/or FIGS. 8A-8D. The plurality of post interconnects 232 may be coupled to the plurality of interconnects 524. The plurality of post interconnects 232 may be considered part of the plurality of interconnects 524.

Stage 11 illustrates a state after a solder resist layer 440 and a solder resist layer 442 are formed. A lamination process and/or a deposition process may be used to formed the solder resist layer 440 and the solder resist layer 442.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package Comprising a Substrate Comprising a Post Interconnect

In some implementations, fabricating a package includes several processes. FIG. 11 illustrates an exemplary sequence for providing or fabricating a package that includes a substrate comprising post interconnects with varying widths. In some implementations, the sequence of FIG. 11 may be used to provide or fabricate the package 500 of FIG. 5. However, the process of FIG. 11 may be used to fabricate any of the packages described in the disclosure.

It should be noted that the sequence of FIG. 11 may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 11 illustrates a state after a substrate 502 is provided. The substrate 502 includes a core layer 520, at least one dielectric layer 521, at least one dielectric layer 523, a plurality of core interconnects 522, a plurality of interconnects 524, a plurality of interconnects 526, a plurality of post interconnects 232, a solder resist layer 440 and a solder resist layer 442. The plurality of post interconnects 232 may be considered part of the plurality of interconnects 524. The plurality of post interconnects 232 includes at least one post interconnect that comprises a profile cross section of a trapezoid shape and/or an inverted trapezoid shape. In some implementations, the substrate 402 may be provided. Different implementations may use different substrates with different numbers of metal layers. A substrate may include a coreless substrate, a cored substrate, or an embedded trace substrate (ETS).

Stage 2 illustrates a state after the integrated device 100 is coupled to the substrate 502 through the plurality of post interconnects 232 and a plurality of solder interconnects 106. A solder reflow process may be used to couple the integrated device 100 to the substrate 502. FIG. 2 illustrates an example of how the integrated device 100 may be coupled to the substrate 502. Different implementations may couple different components and/or devices to the substrate 502.

Stage 3 illustrates a state after an encapsulation layer 408 is provided (e.g., formed) over the substrate 502. The encapsulation layer 408 may encapsulate the integrated device 100. The encapsulation layer 408 may include a mold, a resin and/or an epoxy. A compression molding process, a transfer molding process, or a liquid molding process may be used to form the encapsulation layer 408. The encapsulation layer 408 may be photo etchable. The encapsulation layer 408 may be a means for encapsulation.

Stage 4 illustrates a state after a plurality of solder interconnects 450 are coupled to the substrate 502. A solder reflow process may be used to couple the plurality of solder interconnects 450 to the substrate 502.

### Exemplary Flow Diagram of a Method for Fabricating a Package Comprising a Substrate Comprising a Post Interconnect

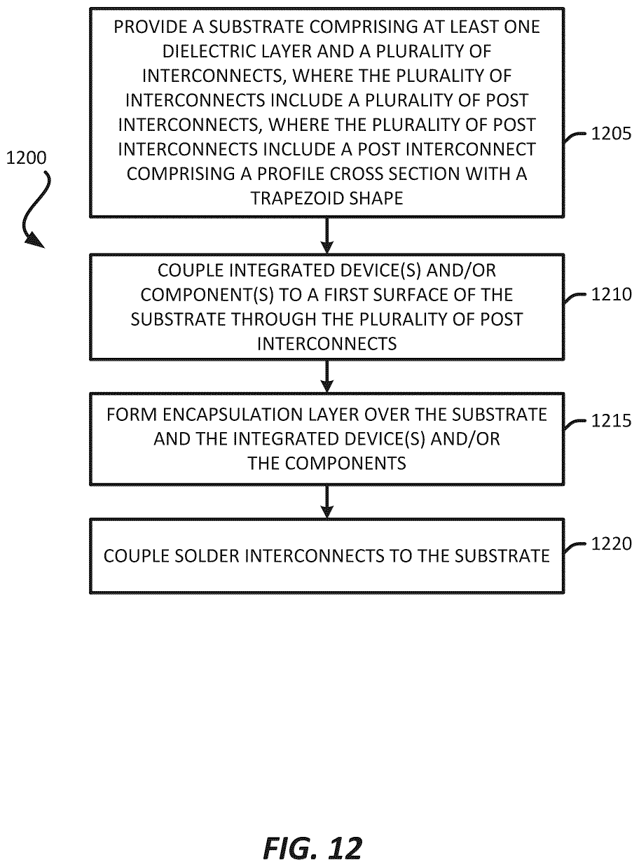

In some implementations, fabricating a package includes several processes. FIG. 12 illustrates an exemplary flow diagram of a method 1200 for providing or fabricating a package comprising a substrate that includes post interconnects with varying widths. In some implementations, the method 1200 of FIG. 12 may be used to provide or fabricate the package 500 of FIG. 5 described in the disclosure. However, the method 1200 may be used to provide or fabricate any of the packages (e.g., 100, 200, 400, 600) described in the disclosure.

It should be noted that the method of FIG. 12 may combine one or more processes in order to simplify and/or clarify the method for providing or fabricating a package. In some implementations, the order of the processes may be changed or modified.

The method provides (at 1205) a substrate (e.g., 202, 402, 502). The substrate 502 may be provided by a supplier or fabricated. Different implementations may use different processes to fabricate the substrate 502. Examples of processes that may be used to fabricate a substrate include a semi-additive process (SAP) and a modified semi-additive process (mSAP). The substrate 502 includes a core layer 520, at least one dielectric layer 521, at least one dielectric layer 523, a plurality of core interconnects 522, a plurality of interconnects 524, a plurality of interconnects 526, a plurality of post interconnects 232, a solder resist layer 440 and a solder resist layer 442. The plurality of post interconnects 232 may be considered part of the plurality of interconnects 524. The plurality of post interconnects 232 include at least one post interconnect that comprises a profile cross section of a trapezoid shape and/or an inverted trapezoid shape. In some implementations, the substrate 402 may be provided. Different implementations may use different substrates with different numbers of metal layers. A substrate may include a coreless substrate, a cored substrate, or an embedded trace substrate (ETS). In some implementations, the at least one dielectric layer may include prepreg layers. Stage 1 of FIG. 11, illustrates and describes an example of providing a substrate.

The method couples (at 1210) an integrated device (e.g., 100) to a first surface of the substrate 502. For example, the integrated device 100 is coupled to a first surface (e.g., top surface) of the substrate 502. The integrated device 100 is coupled to the substrate 502 through the plurality of post interconnects 232 and the plurality of solder interconnects 106. A solder reflow process may be used to couple the integrated device 100 to the substrate 502. FIGS. 2-3 illustrate examples of how integrated devices may be coupled to the substrate 502. Stage 2 of FIG. 11, illustrates and describes an example of coupling an integrated device to a substrate.

The method forms (at 1215) an encapsulation layer (e.g., 408) over the substrate (e.g., 502). The encapsulation layer 408 may be provided and formed over and/or around the substrate 502 and the integrated device 100. The encapsulation layer 408 may include a mold, a resin and/or an epoxy. A compression molding process, a transfer molding process, or a liquid molding process may be used to form the encapsulation layer 408. The encapsulation layer 408 may be photo etchable. The encapsulation layer 408 may be a means for encapsulation. Stage 3 of FIG. 11, illustrates and describes an example of forming an encapsulation layer.

The method couples (at 1220) a plurality of solder interconnects (e.g., 450) to the substrate 502. A solder reflow process may be used to couple the plurality of solder interconnects 450 to the substrate 502. Stage 4 of FIG. 11, illustrates and describes an example of coupling solder interconnects to a substrate.

The packages (e.g., 400, 500, 600) described in the disclosure may be fabricated one at a time or may be fabricated together as part of one or more wafers and then singulated into individual packages.

### Exemplary Electronic Devices

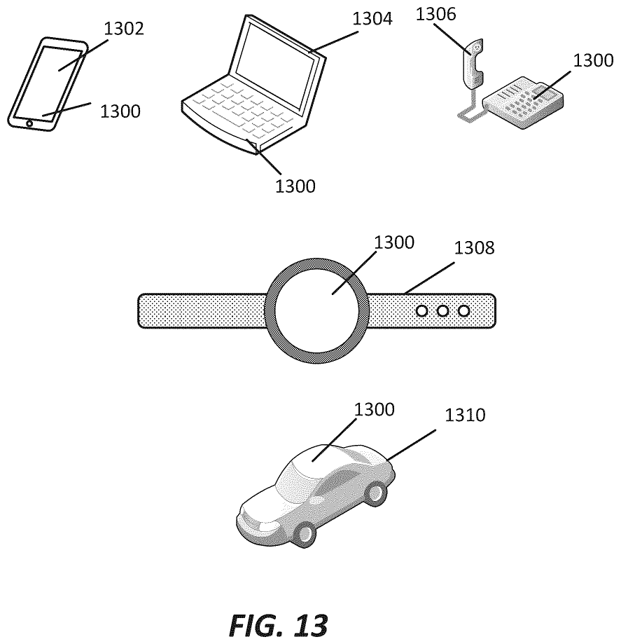

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-6, 7A-7D, 8A-8D, 9A-9B, 10A-10C and/or 11-13 may be rearranged and/or combined into a single component, process, feature or function or embodied in several components, processes, or functions. Additional elements, components, processes, and/or functions may also be added without departing from the disclosure. It should also be noted FIGS. 1-6, 7A-7D, 8A-8D. 9A-9B, 10A-10C and/or 11-13 and its corresponding description in the present disclosure is not limited to dies and/or ICs. In some implementations. FIGS. 1-6, 7A-7D, 8A-8D, 9A-9B, 10A-10C and/or 11-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

Aspect 1: A package comprising an integrated device and a substrate coupled to the integrated device. The substrate comprises at least one dielectric layer and a plurality of interconnects. The plurality of interconnects include a plurality of post interconnects. The plurality of post interconnects include a post interconnect comprising a profile cross section that includes a trapezoid shape.

Aspect 2: The package of aspect 1, wherein the trapezoid shape is an inverted trapezoid shape.

Aspect 3: The package of aspects 1 through 2, wherein the post interconnect is coupled to a pad interconnect from the plurality of interconnects of the substrate.

Aspect 4: The package of aspects 1 through 3, wherein the integrated device is coupled to the plurality of post interconnects through a plurality of solder interconnects.

Aspect 5: The package of aspect 4, wherein the plurality of solder interconnects are located between the integrated device and the plurality of post interconnects.

Aspect 6: The package of aspects 4 through 5, wherein the integrated device comprises a plurality of under bump metallization interconnects, and wherein the plurality of solder interconnects are coupled to the plurality of under bump metallization interconnects and the plurality of post interconnects.

Aspect 7: The package of aspects 1 through 6, wherein the plurality of interconnects comprises a plurality of surface pad interconnects, and wherein the plurality of post interconnects are coupled to the plurality of surface pad interconnects.

Aspect 8: The package of aspects 1 through 7, wherein the trapezoid shape includes a first portion and a second portion, wherein the first portion of the trapezoid shape has a first width, and wherein the second portion of the trapezoid shape has a second width.

Aspect 9: The package of aspect 8, wherein the second width is greater than the first width.

Aspect 10: The package of aspect 9, wherein the first portion is a portion of the trapezoid shape that is vertically farthest away from the integrated device, and wherein the second portion is a portion of the trapezoid shape that is vertically closest to the integrated device.

Aspect 11: A device comprising a package. The package comprises an integrated device and a substrate coupled to the integrated device. The substrate comprises at least one dielectric layer and a plurality of interconnects. The plurality of interconnects include a plurality of post interconnects, and the plurality of post interconnects include a post interconnect comprising a profile cross section that includes a trapezoid shape.

Aspect 12: The device of aspect 11, wherein the trapezoid shape is an inverted trapezoid shape.

Aspect 13: The device of aspects 11 through 12, wherein the post interconnect is coupled to a pad interconnect from the plurality of interconnects of the substrate.

Aspect 14: The device of aspects 11 through 13, wherein the integrated device is coupled to the plurality of post interconnects through a plurality of solder interconnects.

Aspect 15: The device of aspect 14, wherein the plurality of solder interconnects are located between the integrated device and the plurality of post interconnects.

Aspect 16: The device of aspects 14 through 15, wherein the integrated device comprises a plurality of under bump metallization interconnects, and wherein the plurality of solder interconnects are coupled to the plurality of under bump metallization interconnects and the plurality of post interconnects.

Aspect 17: The device of aspects 11 through 16, wherein the plurality of interconnects comprises a plurality of surface pad interconnects, and wherein the plurality of post interconnects are coupled to the plurality of surface pad interconnects.

Aspect 18: The device of aspects 11 through 17, wherein the trapezoid shape includes a first portion and a second portion, wherein the first portion of the trapezoid shape has a first width, and wherein the second portion of the trapezoid shape has a second width.

Aspect 19: The device of aspect 18, wherein the second width is greater than the first width.

Aspect 20: The device of aspects 11 through 19, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 21: A method for fabricating a package. The method provides a substrate comprising at least one dielectric layer and a plurality of interconnects. The plurality of interconnects include a plurality of post interconnects. The plurality of post interconnects include a post interconnect comprising a profile cross section that includes a trapezoid shape. The method couples an integrated device to the substrate through the plurality of post interconnects.

Aspect 22: The method of aspect 21, wherein the trapezoid shape is an inverted trapezoid shape.

Aspect 23: The method of aspects 21 through 22, wherein the post interconnect is coupled to a pad interconnect from the plurality of interconnects of the substrate.

Aspect 24: The method of aspects 21 through 23, wherein the integrated device is coupled to the substrate through a plurality of solder interconnects and the plurality of post interconnects, and wherein the plurality of solder interconnects are located between the integrated device and the plurality of post interconnects.

Aspect 25: The method of aspects 21 through 24, wherein the trapezoid shape includes a first portion and a second portion, wherein the first portion of the trapezoid shape has a first width, wherein the second portion of the trapezoid shape has a second width, wherein the second width is greater than the first width, wherein the first portion is a portion of the trapezoid shape that is farthest away from the integrated device, and wherein the second portion is a portion of the trapezoid shape that is closest to the integrated device.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
an integrated device; and
a substrate coupled to the integrated device, wherein the substrate comprises:
at least one dielectric layer; and
a plurality of interconnects,
wherein the plurality of interconnects include a plurality of post interconnects, and
wherein the plurality of post interconnects include a post interconnect comprising a profile cross section that includes a trapezoid shape.

2. The package of claim 1, wherein the trapezoid shape is an inverted trapezoid shape.

3. The package of claim 1, wherein the post interconnect is coupled to a pad interconnect from the plurality of interconnects of the substrate.

4. The package of claim 1, wherein the integrated device is coupled to the plurality of post interconnects through a plurality of solder interconnects.

5. The package of claim 4, wherein the plurality of solder interconnects are located between the integrated device and the plurality of post interconnects.

6. The package of claim 4,
wherein the integrated device comprises a plurality of under bump metallization interconnects, and
wherein the plurality of solder interconnects are coupled to the plurality of under bump metallization interconnects and the plurality of post interconnects.

7. The package of claim 1,
wherein the plurality of interconnects comprise a plurality of surface pad interconnects, and
wherein the plurality of post interconnects are coupled to the plurality of surface pad interconnects.

8. The package of claim 1,
wherein the trapezoid shape includes a first portion and a second portion,
wherein the first portion of the trapezoid shape has a first width, and
wherein the second portion of the trapezoid shape has a second width.

9. The package of claim 8, wherein the second width is greater than the first width.

10. The package of claim 9,
wherein the first portion is a portion of the trapezoid shape that is vertically farthest away from the integrated device, and
wherein the second portion is a portion of the trapezoid shape that is vertically closest to the integrated device.

11. A device comprising:
a package comprising:
an integrated device; and
a substrate coupled to the integrated device, wherein the substrate comprises:
at least one dielectric layer; and
a plurality of interconnects,
wherein the plurality of interconnects include a plurality of post interconnects, and
wherein the plurality of post interconnects include a post interconnect comprising a profile cross section that includes a trapezoid shape.

12. The device of claim 11, wherein the trapezoid shape is an inverted trapezoid shape.

13. The device of claim 11, wherein the post interconnect is coupled to a pad interconnect from the plurality of interconnects of the substrate.

14. The device of claim 11, wherein the integrated device is coupled to the plurality of post interconnects through a plurality of solder interconnects.

15. The device of claim 14, wherein the plurality of solder interconnects are located between the integrated device and the plurality of post interconnects.

16. The device of claim 14,
wherein the integrated device comprises a plurality of under bump metallization interconnects, and
wherein the plurality of solder interconnects are coupled to the plurality of under bump metallization interconnects and the plurality of post interconnects.

17. The device of claim 11,
wherein the plurality of interconnects comprise a plurality of surface pad interconnects, and
wherein the plurality of post interconnects are coupled to the plurality of surface pad interconnects.

18. The device of claim 11,
wherein the trapezoid shape includes a first portion and a second portion,
wherein the first portion of the trapezoid shape has a first width, and
wherein the second portion of the trapezoid shape has a second width.

19. The device of claim 18, wherein the second width is greater than the first width.

20. The device of claim 11, wherein the device is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

21. A method for fabricating a package, comprising:
providing a substrate comprising:
at least one dielectric layer; and
a plurality of interconnects,
wherein the plurality of interconnects include a plurality of post interconnects, and
wherein the plurality of post interconnects include a post interconnect comprising a profile cross section that includes a trapezoid shape, and
coupling an integrated device to the substrate through the plurality of post interconnects.

22. The method of claim 21, wherein the trapezoid shape is an inverted trapezoid shape.

23. The method of claim 21, wherein the post interconnect is coupled to a pad interconnect from the plurality of interconnects of the substrate.

24. The method of claim 21,
wherein the integrated device is coupled to the substrate through a plurality of solder interconnects and the plurality of post interconnects, and
wherein the plurality of solder interconnects are located between the integrated device and the plurality of post interconnects.

25. The method of claim 21, wherein the trapezoid shape includes a first portion and a second portion, wherein the first portion of the trapezoid shape has a first width, wherein the second portion of the trapezoid shape has a second width, wherein the second width is greater than the first width, wherein the first portion is a portion of the trapezoid shape that is farthest away from the integrated device, and wherein the second portion is a portion of the trapezoid shape that is closest to the integrated device.
